(19) United States
(12) Patent Application Publication
(10) Pub. No.: US 2013/0056823 A1
(43) Pub. Date: Mar. 7, 2013

(54) SEMICONDUCTOR DEVICES

(71) Applicants: Yoonjae Kim, Yongin-si (KR); Nam-Gun Kim, Suwon-si (KR); Chulho Shin, Yongin-si (KR); Chan Min Lee, Hwaseong-si (KR)

(72) Inventors: Yoonjae Kim, Yongin-si (KR); Nam-Gun Kim, Suwon-si (KR); Chulho Shin, Yongin-si (KR); Chan Min Lee, Hwaseong-si (KR)

(21) Appl. No.: 13/603,045

(22) Filed: Sep. 4, 2012

(30) Foreign Application Priority Data
Sep. 5, 2011 (KR) 10-2011-0089771

(51) Int. Cl. H01L 29/78

(52) U.S. Cl. 257/334; 257/E29.262

(57) ABSTRACT

A device isolation layer is formed in a substrate to define spaced-apart linear active regions in the substrate. Buried gate patterns are formed in the substrate and extending along a first direction to cross the active regions. An etch stop layer and a first insulating layer are formed on the substrate. Bit line structures are formed on the first insulating layer and extending along a second direction transverse to the first direction to cross the active regions. A second insulating layer is formed on the bit line structures. Contact plugs are formed penetrating the second insulating layer, the first insulating layer, and the etch stop layer to contact one of the active regions between adjacent ones of the bit line structures.

### CROSS-REFERENCE TO RELATED APPLICATIONS

This U.S. non-provisional patent application claims priority under 35 U.S.C. §119 to Korean Patent Application No. 10-2011-0089771, filed on Sep. 5, 2011, the entirety of which is incorporated by reference herein.

### BACKGROUND

The inventive subject matter relates to semiconductor devices and methods of fabricating the same and, more particularly, to semiconductor memory devices including buried channel array transistors and methods of fabricating the same.

As semiconductor devices become highly integrated, it may be difficult to secure a stable transistor operation. Buried channel array transistors (BCATs) have been investigated as a potential way to overcome short channel effects and reduce transistor size.

Semiconductor devices, such as dynamic random access memory (DRAM) devices, may include buried channel array transistors. A semiconductor substrate having such an array of buried channel array transistors may be covered by an interlayer insulating layer. Bit lines may be disposed on the interlayer insulating layer. The bit lines may be connected to source/drain regions through contact plugs. The contact plugs may be formed in contact holes penetrating the interlayer insulating layer.

Forming the contact holes may require a high accuracy patterning process. For example, even though a contact hole may be slightly misaligned from the source/drain region, a leakage current may occur between the contact plug and a gate electrode. Additionally, such a patterning process may decrease production efficiency and increase fabricating cost.

### SUMMARY

Embodiments of the inventive subject matter provide methods of fabricating semiconductor devices. A device isolation layer is formed in a substrate to define spaced-apart linear active regions in the substrate. Buried gate patterns are formed in the substrate and extending along a first direction to cross the active regions. An etch stop layer and a first insulating layer are formed on the substrate. Bit line structures are formed on the first insulating layer and extending along a second direction transverse to the first direction to cross the active regions. A second insulating layer is formed on the bit line structures. Contact plugs are formed penetrating the second insulating layer, the first insulating layer, and the etch stop layer to contact one of the active regions between adjacent ones of the bit line structures.

Forming the buried gate patterns may include forming a trench in the substrate, forming a cell gate insulating layer on an inner surface of the trench, forming a cell gate electrode on the cell gate insulating layer in the trench, and forming a cell gate capping pattern on the cell gate electrode in the trench.

Forming the bit line structures may include sequentially forming a barrier layer, a metal layer, and a capping layer on the first insulating layer and patterning the capping layer, the metal layer, and the barrier layer.

In some embodiments, the contact plug may include a first contact plug, forming the bit line structures may include forming an opening in the etch stop layer and the first insulating layer exposing a portion of an active region between adjacent buried gate patterns and forming a second contact plug in the opening and forming the bit line structures may include forming a bit line structure on and electrically connected to the second contact plug. The second contact plug may include polysilicon.

In some embodiments, the substrate may include a cell region and a peripheral region and the buried gate patterns may be formed in the cell region. The methods may further include forming a gate pattern including a peripheral gate insulating layer, a peripheral gate electrode, and an upper structure sequentially stacked on an active region in the peripheral region, wherein the upper structure is formed of the same material as the bit line structures. The bit line structures and the upper structure are formed by the same processes. A portion of the etch stop layer on the device isolation layer between the cell region and the peripheral region may have a height lower than a height of the peripheral gate electrode.

Some embodiments provide a semiconductor device including a substrate and a device isolation layer defining active regions in the substrate. The device also includes buried gate patterns in the substrate extending along a first direction and crossing the active regions, an etch stop layer and a first insulating layer stacked on the substrate and first contact plugs penetrating the first insulating layer and the etch stop layer to electrically contact the active regions between the buried gate patterns. Bit line structures are disposed on the first insulating layer and electrically connected to the first contact plugs, the bit line structures extending in a second direction transverse to the first direction. A second insulating layer covers the bit line structures. Second contact plugs penetrate the second insulating layer, the first insulating layer, and the etch stop layer to electrically contact the active regions between the bit line structures.

The buried gate patterns may each include a cell gate insulating layer disposed on an inner surface of a trench in the substrate, a cell gate electrode on the cell gate insulating layer in the trench and a cell gate capping pattern disposed on the cell gate electrode in the trench.

The bit line structures may each include a barrier pattern, a metal pattern, and a capping pattern stacked on the first insulating layer.

The first contact plugs may include polysilicon.

The substrate may include a cell region and a peripheral region and the buried gate patterns may be disposed in the cell region. The device may further include a gate pattern including a peripheral gate insulating layer, a peripheral gate electrode, and an upper structure stacked on an active region in the peripheral region, wherein the upper structure includes the same material as the bit line structures. A portion of the etch stop layer on the device isolation layer between the cell region and the peripheral region may have a height lower than a height of the peripheral gate electrode.

In further embodiments, a semiconductor device includes a substrate and a device isolation layer defining elongate active regions in the substrate. The device also includes parallel linear buried gate patterns in the substrate extending along a first direction to obliquely crossing the active regions. A first insulating layer is disposed on the parallel linear buried gate patterns. First contact plugs penetrate the first insulating layer to electrically contact the active regions between the parallel linear buried gate patterns. Parallel linear bit line structures are disposed on the first insulating layer and electrically connected to the first contact plugs, the bit line structures extending in a second direction transverse to the first direction to obliquely cross the active regions. A second insulating layer covers the parallel linear bit line structures. Second contact plugs penetrate the second insulating layer and the first insulating layer to electrically contact the active regions between the bit line structures.

The device may further include an etch stop layer on the parallel linear buried gate patterns, wherein the first insulation layer is disposed on the etch stop layer, and wherein the first and second contact plugs pass through the etch stop layer.

In some embodiments, the substrate may include a cell region and a peripheral region and the buried gate patterns may be disposed in the cell region. The device may further include a gate pattern including a peripheral gate insulating layer, a peripheral gate electrode, and an upper structure stacked on an active region in the peripheral region, wherein the upper structure includes the same material as the bit line structures. A portion of the etch stop layer on the device isolation layer between the cell region and the peripheral region may have a height lower than a height of the peripheral gate electrode.

### BRIEF DESCRIPTION OF THE DRAWINGS

The inventive subject matter will become more apparent in view of the attached drawings and accompanying detailed description.

FIG. 1 is a plan view illustrating a semiconductor device according to some embodiments of the inventive subject matter;

FIG. 2A is a merged cross sectional view taken along lines A-A′, B-B′, and C-C′ of FIG. 1 to illustrate a semiconductor device according to some embodiments of the inventive subject matter;

FIG. 2B is a merged cross sectional view taken along a line F-F′ of FIG. 1 to illustrate a semiconductor device according to some embodiments of the inventive subject matter;

FIGS. 3A and 3B are enlarged views of a portion ‘E’ of FIG. 2B;

FIGS. 4 to 13 are merged cross sectional views taken along lines A-A′, B-B′, and C-C′ of FIG. 1 to illustrate operations for fabricating a semiconductor device according to some embodiments of the inventive subject matter;

FIG. 14 is a schematic block diagram illustrating an example of memory systems including semiconductor devices according to some embodiments of the inventive subject matter;

FIG. 15 is a schematic block diagram illustrating an example of memory cards including semiconductor devices according to some embodiments of the inventive subject matter; and

FIG. 16 is a schematic block diagram illustrating an example of data processing systems including semiconductor devices according to some embodiments of the inventive subject matter.

### DETAILED DESCRIPTION

The inventive subject matter will now be described more fully hereinafter with reference to the accompanying drawings, in which exemplary embodiments of the inventive subject matter are shown. The advantages and features of the inventive subject matter and methods of achieving them will be apparent from the following exemplary embodiments that will be described in more detail with reference to the accompanying drawings. It should be noted, however, that the inventive subject matter is not limited to the following exemplary embodiments, and may be implemented in various forms. Accordingly, the exemplary embodiments are provided only to disclose the inventive subject matter and let those skilled in the art know the category of the inventive subject matter. In the drawings, embodiments of the inventive subject matter are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive subject matter. Accordingly, shapes of the exemplary views may be modified according to manufacturing techniques and/or allowable errors. Therefore, the embodiments of the inventive subject matter are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive subject matter.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive subject matter explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

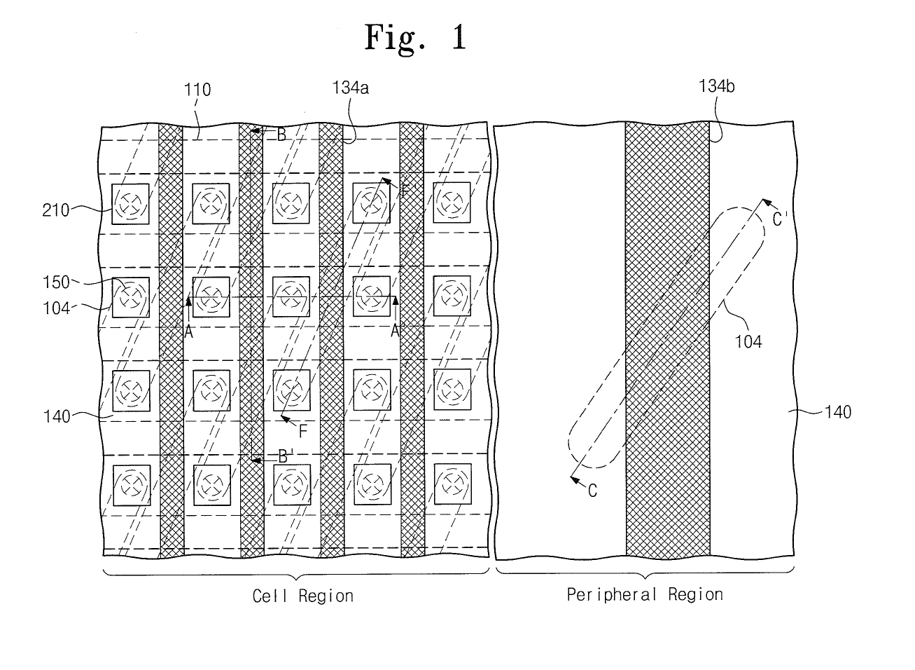

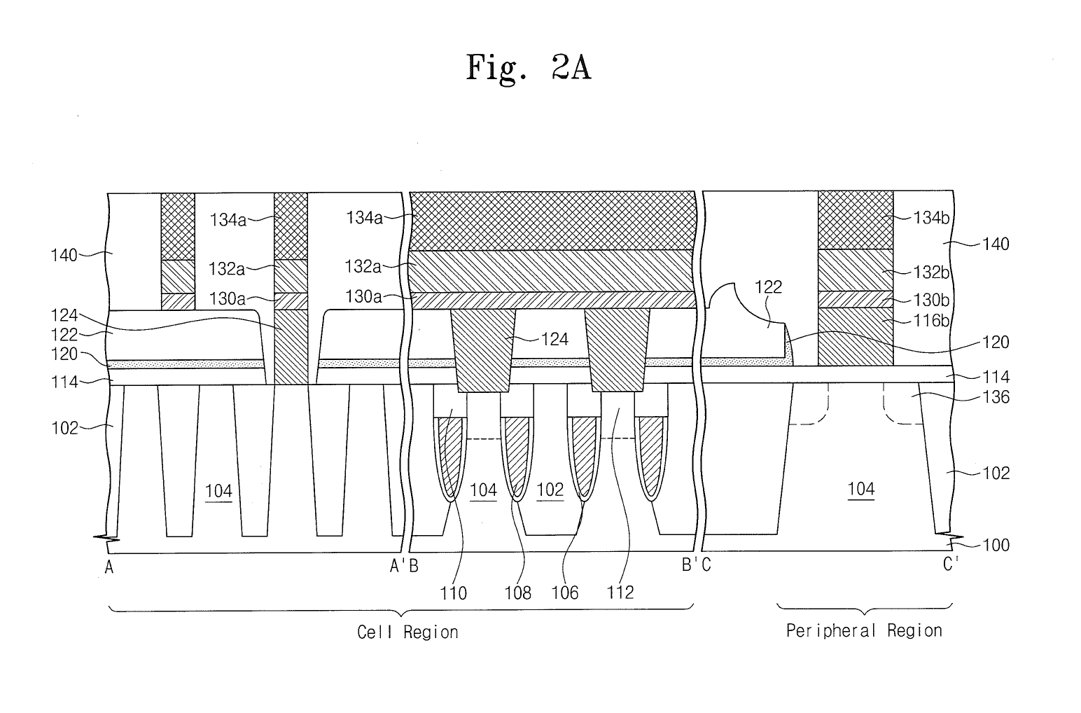

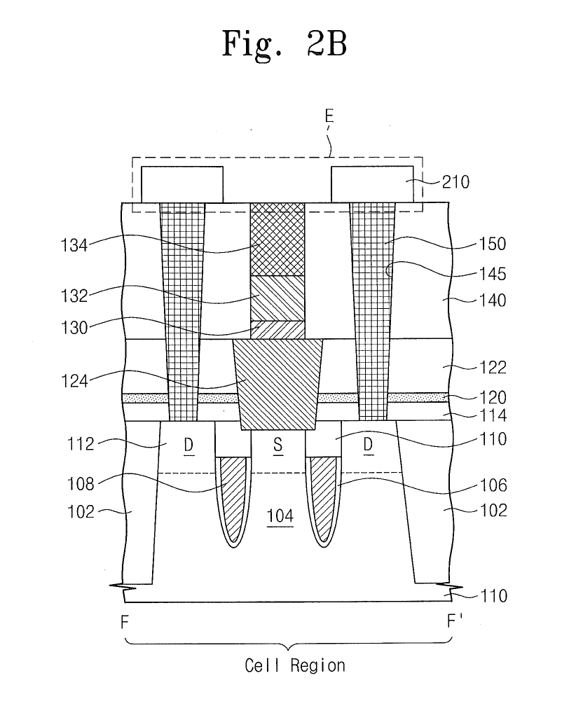

FIG. 1 is a plan view illustrating a semiconductor device according to some embodiments of the inventive subject matter, FIG. 2A is a merged cross sectional view taken along lines A-A′, B-B′, and C-C′ of FIG. 1 to illustrate a semiconductor device according to some embodiments of the inventive subject matter, and FIG. 2B is a merged cross sectional view taken along a line F-F′ of FIG. 1 to illustrate a semiconductor device according to some embodiments of the inventive subject matter.

Referring to FIGS. 1, 2A, and 2B, a substrate 100 may include a cell region and a peripheral region. Buried channel array transistors may be disposed in the cell region and a non-buried transistor may be disposed in the peripheral region.

A device isolation layer 102 may be disposed in the substrate 100 to define active regions 104. The device isolation layer 102 may be a shallow trench isolation (STI) type device isolation layer. However, the inventive subject matter is not limited thereto. The device isolation layer 102 may include an insulating material. For example, the device isolation layer 102 may include silicon oxide, silicon nitride, and/or silicon oxynitride. The substrate 100 may include a semiconductor material. For example, the substrate 100 may include silicon (Si) and/or germanium (Ge).

A trench may be disposed in the substrate 100 of the cell region. As illustrated in FIGS. 1, 2A, and 2B, the trench may have a linear shape and may extend in a first direction to cross the active regions 104 and the device isolation layer 102 of the cell region when viewed from a top view. In some embodiments, a pair of the trenches may cross the active region 104 of the cell region.

A cell gate electrode 108 may be disposed in the trench. As illustrated in FIGS. 1, 2A, and 2B, the cell gate electrode 108 may have a linear shape crossing the active region 104 and the device isolation layer 102 of the cell region when viewed from a top view. A top surface of the cell gate electrode 108 may be disposed at a level lower than a top surface of the substrate 100. Thus, the cell gate electrode 108 may be buried in the trench.

In some embodiments, as illustrated in FIG. 1, since the pair of the trenches cross the active region 104 of the cell region, a pair of the cell gate electrodes 108 may cross the active region 104 of the cell region. The cell gate electrode 108 may include a conductive material. For example, the cell gate electrode 108 may include a semiconductor doped with dopants, a conductive metal nitride (e.g., titanium nitride (TiN), tantalum nitride (TaN), and/or tungsten nitride (WN)), and/or metal (e.g., ruthenium (Ru), iridium (Ir), titanium (Ti), tungsten (W), and/or tantalum (Ta)).

A cell gate insulating layer 106 may be disposed between the cell gate electrode 108 and an inner surface of the trench. The cell gate insulating layer 106 may include oxide, nitride, oxynitride, and/or a high-k dielectric material. The high-k dielectric material may be an insulating material having a dielectric constant higher than that of nitride. For example, the high-k dielectric material may include insulating metal oxides such as hafnium oxide and/or aluminum oxide. In some embodiments, the cell gate insulating layer 106 may have a cross section of a “U” shape contacting an entire inner surface of the trench.

A cell gate capping pattern 110 may be disposed on the cell gate electrode 108. The cell gate capping pattern 110 may fill a portion of the trench. The cell gate capping pattern 110 may include an insulating material. For example, the cell gate capping pattern 110 may include oxide, nitride, and/or oxynitride.

Cell dopant regions 112 may be disposed in the active region 104 at both sides of the trenches. The cell dopant regions 112 may correspond to source and drain regions S and D. In some embodiments, a common source region S and a pair of drain regions D may be disposed in the active region 104 of the cell region. The common source region S may be disposed in the active region 104 between the pair of the cell gate electrodes 108. The pair of the cell gate electrodes 108 and the common source region S may be disposed between the pair of drain regions D.

Bottom surfaces of the cell dopant regions 112 may be disposed at a predetermined depth from the top surface of the active region 104. The cell dopant regions 112 may be in contact with sidewalls of the trenches. The cell dopant regions 112 may be doped with dopants. For example, the cell dopant regions 112 may be doped with phosphorus (P) and/or boron (B). In some embodiments, bottom surfaces of the cell dopant regions 112 may be disposed at a level higher than a bottom surface of the trench.

A peripheral gate insulating layer 114 may be disposed on the substrate 100. The peripheral gate insulating layer 114 may include oxide, nitride, oxynitride and/or a high-k dielectric material. The high-k dielectric material may be an insulating material having a dielectric constant higher than that of nitride. For example, the high-k dielectric material may include insulating metal oxides such as hafnium oxide and/or aluminum oxide.

A peripheral gate electrode 116a may be disposed on the peripheral gate insulating layer 114 disposed on the active region 104 in the peripheral region. The peripheral gate electrode 116a may include a semiconductor doped with dopants (e.g., doped poly silicon), a conductive metal nitride (e.g., titanium nitride (TiN), tantalum nitride (TaN), and/or tungsten nitride (WN)), and/or metal (e.g., ruthenium (Ru), iridium (Ir), titanium (Ti), tungsten (W), and/or tantalum (Ta)).

In the peripheral region, peripheral dopant regions 136 may be disposed in the active region 104 at both sides of the peripheral gate electrode 116a. The peripheral dopant regions 136 may correspond to source and drain regions. Bottom surfaces of the peripheral dopant regions 136 may be disposed at a predetermined depth from the top surface of the active region 104 of the peripheral region. The peripheral dopant regions 136 may be doped with dopants. For example, the peripheral dopant regions 136 may be doped phosphorus (P) and/or boron (B). In some embodiments, the bottom surfaces of the peripheral dopant regions 136 may be disposed at a level higher than the bottom surface of the device isolation layer 102.

An etch stop layer 120 may be disposed on the peripheral gate insulating layer 114 of the cell region. The etch stop layer 120 may include oxide, nitride, and/or oxynitride. The etch stop layer 120 may include a material having an etch selectivity with respect to the peripheral gate insulating layer 114. The etch stop layer 120 may further extend on the device isolation layer 102 between the cell region and the peripheral region, and the etch stop layer 120 may have a height smaller than a height of the peripheral gate electrode 116a of the peripheral region. Since the etch stop layer 120 is disposed under a bit line structure, it is possible to reduce a recessed depth of the substrate 100 of the active regions and to improve uniformity of the recessed depths throughout the substrate 100 in an etching process for formation of a second contact plug 150. Thus, refresh deterioration may be reduced to realize a semiconductor device with improved reliability.

A first insulating layer 122 may be disposed on the etch stop layer 120 of the cell region. The first insulating layer 122 may be single-layered or multi-layered. The first insulating layer 122 may include oxide, nitride, and/or oxynitride. The first insulating layer 122 may include a material having an etch selectivity with respect to the etch stop layer 120.

A first contact plug 124 may successively penetrate the first insulating layer 122, the etch stop layer 120, and the peripheral gate insulating layer 114 in the cell region. The first contact plug 124 may be electrically connected to the active region 104 between the pair of the cell gate electrodes 106. The first contact plug 124 may be disposed to be in contact with the common source region S adjacent to the trench. The first contact plug 124 may include a conductive material. For example, the first contact plug 124 may include a doped semiconductor material (e.g., doped polysilicon), a metal-semiconductor compound (e.g., metal silicide such as tungsten silicide and/or titanium silicide), a conductive metal nitride (e.g., titanium nitride, tantalum nitride, and/or tungsten nitride), and/or metal (e.g., titanium, tungsten, and/or tantalum). In some embodiments, the first contact plug 124 may be formed of doped polysilicon.

A bit line structure may be disposed on the first insulating layer 122 of the cell region. The bit line structure may include a barrier pattern 130a, a metal pattern 132a, and a capping pattern 134a sequentially stacked on the first insulating layer 122 of the cell region. In a plan view, the bit line structure may have a linear shape extending in a direction transverse to the direction of the trench in which the cell gate electrode 108 is formed. The barrier pattern 130a may include a conductive metal nitride (e.g., titanium nitride, tantalum nitride, and/or tungsten nitride). The metal pattern 132a may include metal (e.g., ruthenium (Ru), iridium (Ir), titanium (Ti), tungsten (W), and/or tantalum (Ta)). The capping pattern 134a may include oxide, nitride, and/or oxynitride.

An upper structure may be disposed on the peripheral gate electrode 116a. The upper structure may includes a second barrier pattern 130b, a second metal pattern 132b, and a second capping pattern 134b sequentially stacked. The second barrier pattern 130b may be formed of the same material as the barrier pattern 130a, the second metal pattern 132b may be formed of the same material as the metal pattern 132a, and the second capping pattern 134b may be formed of the same material as the capping pattern 134a.

A second insulating layer 140 exposing top surface of the bit line structure and the upper structure may be disposed on the first insulating layer 122. The second insulating layer 140 may be single-layered or multi-layered. The second insulating layer 140 may include oxide, nitride, and/or oxynitride.

As illustrated in FIG. 2B, a second contact plug 150 may successively penetrate the second insulating layer 140, the first insulating layer 122, the etch stop layer 120, and the peripheral gate insulating layer 114 in the cell region. The second contact plug 150 may be disposed to be in contact with the drain region D adjacent to the trench.

The second contact plug 150 may include a conductive material. For example, the second contact plug 150 may include a doped semiconductor material (e.g., doped polysilicon), a metal-semiconductor compound (e.g., metal silicide such as tungsten silicide and/or titanium silicide), a conductive metal nitride (e.g., titanium nitride, tantalum nitride, and/or tungsten nitride), and/or metal (e.g., titanium, tungsten, and/or tantalum).

A data storage element 210 may be disposed on the second insulating layer 140 to be electrically connected to the second contact plug 150. The data storage element 210 may be realized in various forms.

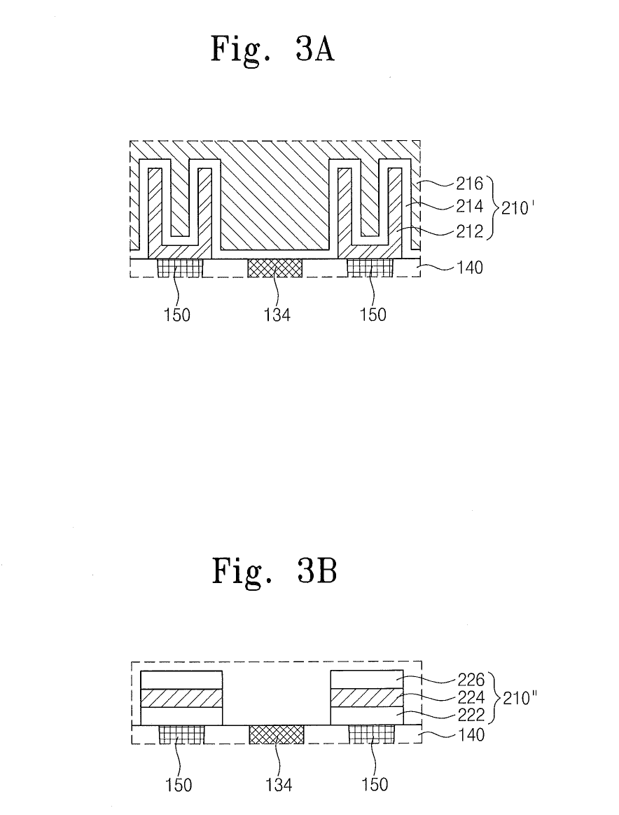

FIGS. 3A and 3B are enlarged views of a portion ‘E’ of FIG. 2B. FIG. 3A is an enlarged cross sectional view illustrating exemplary implementation for the data storage element 210 according some embodiments, and FIG. 3B is an enlarged cross sectional view illustrating an implementation for the data storage element 210 according further embodiments.

The data storage element 210 of FIG. 2B may be a capacitor according to some embodiments. For example, a capacitor data storage element 210′ shown in FIG. 3A includes a lower electrode (or a storage node) 212 contacting the second contact plug 150. The lower electrode 212 may have a cylinder shape. In other words, the lower electrode 212 may include a flat portion contacting the second contact plug and a sidewall portion upward extending from an edge of the flat portion. The lower electrode 212 may include a conductive material. For example, the lower electrode 212 may include a doped semiconductor material, a conductive metal nitride (e.g., titanium nitride, tantalum nitride, and/or tungsten nitride), metal (e.g., ruthenium (Ru), iridium (Ir), titanium (Ti), and/or tantalum (Ta)), and/or a conductive metal oxide (e.g., iridium oxide).

A dielectric layer 214 may be conformally disposed on a surface of the lower electrode 212. The dielectric layer 214 may cover an entire surface of the lower electrode 212. Additionally, the dielectric layer 214 may further cover a portion of the top surface of the second insulating layer 140. The dielectric layer 214 may include oxide, nitride, oxynitride, and/or a high-k dielectric material.

An upper electrode 216 may be disposed on the dielectric layer 214 to cover the lower electrode 212. The upper electrode 216 may include a conductive material. For example, the upper electrode 216 may include a doped semiconductor material, metal, a conductive metal nitride, and/or metal silicide.

According to further embodiments, the data storage element 210 of FIG. 2B may be a variable resistor. Referring to FIG. 3B, a data storage element 210″ according to some embodiments may include a first electrode 222, the variable resistor 224, and a second electrode 226. The variable resistor 224 may be disposed between the first electrode 222 and the second electrode 226. Thus, the first electrode 222, the variable resistor 224, and the second electrode may be sequentially stacked on the second insulating layer 140.

In some embodiments, the variable resistor 224 may include a phase change material. The phase change material at least one chalcogenide element such as tellurium (Te) and/or selenium (Se). In addition, the phase change material may further include germanium (Ge), antimony (Sb), bismuth (Bi), lead (Pb), tin (Sn), argentum (Ag), arsenic (As), sulfur (S), silicon (Si), phosphorus (P), oxygen (O) and/or nitrogen (N). For example, the variable resistor 224 may include Ge—Sb—Te, As—Sb—Te, As—Ge—Sb—Te, Sn—Sb—Te, Ag—In—Sb—Te, In—Sb—Te, a group 5A element-Sb—Te, a group 6A element-Sb—Te, a group 5A element-Sb—Se, and/or a group 6A element-Sb—Se.

The first electrode 222 and the second electrode 226 may include a conductive material with lower reactivity. For example, the first electrode 222 and the second electrode 226 may include a conductive metal nitride (e.g., titanium nitride, tantalum nitride, and/or titanium-aluminum nitride). In other embodiments, the first electrode 222 may serve as a heater electrode. The first electrode 222 may transmit heat to the variable resistor 224, such that the variable resistor 224 may be changed into an amorphous state or a crystalline state. The data storage element 210″ may store data using resistivity differences between an amorphous state and a crystalline state of the variable resistor 224.

The data storage element 210″ may further include an ohmic layer disposed between the second contact plug 150 and the first electrode 222. The ohmic layer may include, for example, a metal-semiconductor compound. For example, the ohmic layer may include a cobalt-semiconductor compound (e.g., cobalt silicide (CoSi)), a nickel-semiconductor compound (e.g., nickel silicide (NiSi)), and/or a titanium-semiconductor compound (e.g., titanium silicide (TiSi)).

In other embodiments, the variable resistor 224 may include a transition metal oxide. For example, the transition metal oxide of the variable resistor 224 may include nickel (Ni), niobium (Nb), titanium (Ti), zirconium (Zr), hafnium (Hf), cobalt (Co), iron (Fe), copper (Cu), and/or chromium (Cr).

In this case, the first electrode 222 and the second electrode 226 may include a conductive material. For example, the first electrode 222 and the second electrode 226 may include aluminum (A), gold (Au), platinum (Pt), ruthenium (Ru), iridium (Ir), and/or titanium (Ti). According to other embodiments, the data storage element 210″ including the transition metal oxide may store data using resistance-change of the variable resistor 224 including the transition metal oxide according to voltages applied to the first and second electrodes 222 and 226.

In still other embodiments, the variable resistor 224 may include a magnetic tunnel junction (MTJ) pattern. In this case, the variable resistor 224 may include a free layer, a reference layer, and a tunnel barrier layer disposed between the free layer and the reference layer. A magnetization direction of the free layer may be changeable and the reference layer may have a fixed magnetization direction.

In devices according to the aforementioned embodiments, since the etch stop layer 120 is formed under the bit line structure subsequently formed, it is possible to reduce a recessed depth of the substrate 100 of the active regions and to improve uniformity of the recessed depths throughout the substrate 100 in the subsequent etching process for formation of the second contact plug 150. Thus, refresh deterioration may be reduced to realize devices with improved reliability.

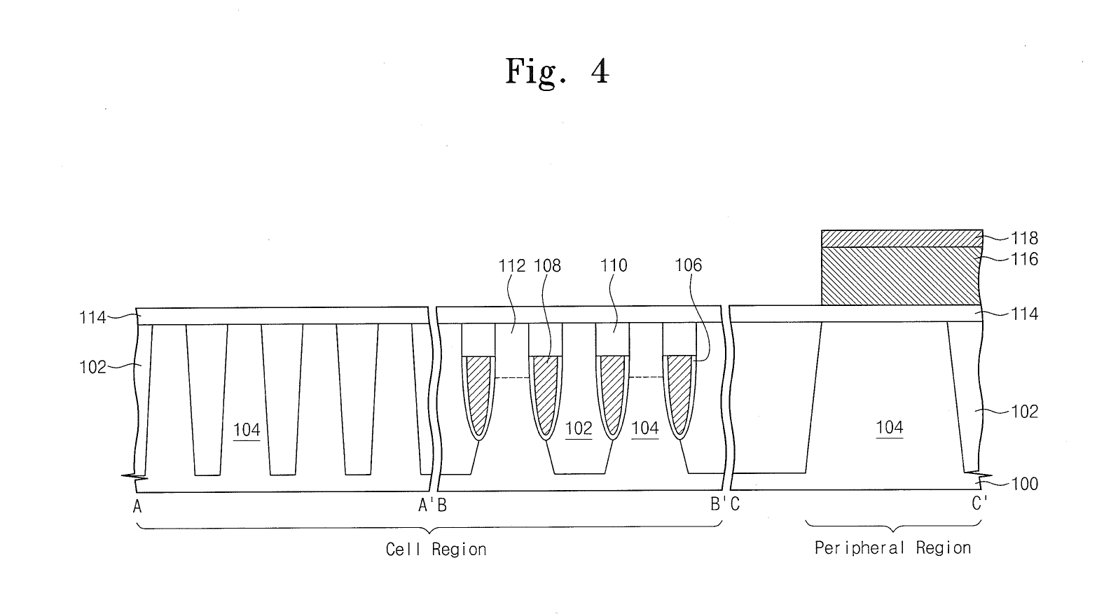

FIGS. 4 to 13 are merged cross sectional views taken along lines A-A′, B-B′, and C-C′ of FIG. 1 to illustrate operations for fabricating a semiconductor device according to some embodiments of the inventive subject matter.

Referring to FIG. 4, a substrate 100 having a cell region and a peripheral region defined therein may be prepared. The substrate 100 may include active regions 104 and a device isolation layer 102 defining the active regions 104. The substrate 100 may include a semiconductor material. For example, the substrate 100 may include silicon and/or germanium.

The device isolation layer 102 may be formed by forming a groove in the substrate 100, forming an insulating layer on entire surface of the substrate to fill the groove, and etching the insulating layer until a top surface of the substrate 100 is exposed. The device isolation layer 102 may include an insulating material. For example, the device isolation layer 102 may include oxide, nitride, and/or oxynitride.

A trench may be formed in the cell region. The trench may extend in a first direction to have a linear shape crossing the active regions and the device isolation layer 102 in the cell region. In some embodiments, a pair of the trenches may cross the active region 102 of the cell region.

A mask pattern may be formed on the substrate 100 and the substrate 100 may be etched using the mask pattern as an etch mask to form the trench. The substrate 100 may be etched by using, for example, a dry etching process.

A cell gate insulating layer 106 may be conformally formed on the top surface of the substrate 100 and an inner surface of the trench. The cell gate insulating layer 106 may be formed, for example, by an oxidation process. The oxidation process may be performed one more times.

Alternatively, the cell gate insulating layer 106 may be formed by a chemical vapor deposition (CVD) process and/or an atomic layer deposition (ALD) process. The cell gate insulating layer 106 may include oxide, nitride, oxynitride, and/or a high-k dielectric material. The high-k dielectric material may be an insulating material having a dielectric constant higher than that of nitride. For example, the high-k dielectric material may include an insulating metal oxide, such as hafnium oxide and/or aluminum oxide.

A cell gate electrode layer may be formed on the surface of the substrate 100 to fill at least lower portion of the trench. The cell gate electrode layer may be formed, for example, by a physical vapor deposition (PVD) process, a CVD process, and/or an ALD process. The cell gate electrode layer may include a semiconductor doped with dopants, a conductive metal nitride (e.g., titanium nitride (TiN), tantalum nitride (TaN), and/or tungsten nitride (WN)), and/or a metal (e.g., ruthenium (Ru), iridium (Ir), titanium (Ti), tungsten (W), and/or tantalum (Ta)).

Before the cell gate electrode layer is formed, a surface treatment process may be performed on the substrate 100 having the cell gate insulating layer 106. The surface treatment process may be a nitridation treatment process and/or an ozone treatment process. Due to the surface treatment process, it is possible to minimize layers formed at an interface between the cell gate insulating layer 106 and the cell gate electrode layer by a foreign substance. Thus, reliability and electric characteristic of the semiconductor device may be improved.

The cell gate electrode layer may be etched to form a cell gate electrode 108. A top surface of the cell gate electrode 108 may be disposed at a level lower than the top surface of the substrate 100. Thus, the cell gate electrode 108 may be confined to the trench. The cell gate electrode layer may be etched by using, for example, a dry etching process and/or a chemical mechanical polishing (CMP) process. The cell gate insulating layer 106 may have a cross section of a “U” shape covering sidewalls and a bottom surface of the cell gate electrode 108.

In some embodiments, since the pair of the trenches may cross the active region 104 of the cell region, a pair of the cell gate electrodes 108 may cross the active region 104 of the cell region.

A cell gate capping pattern 110 may be formed on the cell gate electrode 108. A cell gate capping layer may be formed on the entire surface of the substrate 100 and the cell gate capping layer may be etched until the top surface of the substrate 100 is exposed. Thus, the cell gate capping pattern 110 may be formed. The cell gate capping layer may be formed by a CVD process. The cell gate capping layer may be etched by a CMP process, a dry etching process, and/or a wet etching process. The cell gate capping pattern 110 may include an insulating material. For example, the cell gate capping pattern 110 may include oxide, nitride, and/or oxynitride.

In some embodiments, an insulating layer may be disposed between the cell gate electrode 108 and the cell gate capping pattern 110.

Cell dopant regions 112 may be formed in the active region 104 at both sides of the trenches. The cell dopant regions 112 may correspond to source and drain regions. In some embodiments, the common source region and a pair of the drain regions may be formed in the active region as described with reference to FIG. 2B. The common source region may be formed in the active region 104 between the pair of the cell gate electrodes 108. The pair of the cell gate electrodes 108 and the common source region may be formed between the pair of drain regions.

Bottom surfaces of the cell dopant regions 112 may be formed at a predetermined depth from the top surface of the active region 104. The cell dopant regions 112 may be in contact with sidewalls of the trenches. The cell dopant regions 112 may be formed by injecting dopants into the active region 104 of the cell region. For example, the dopant may be doped with phosphorus (P) and/or boron (B). In some embodiments, bottom surfaces of the cell dopant regions 112 may be disposed at a level higher than a bottom surface of the trench.

A peripheral gate insulating layer 114 may be formed on the surface of the substrate 100. The peripheral gate insulating layer 114 may include oxide, nitride, oxynitride, and/or a high-k dielectric material. The high-k dielectric material may be an insulating material having a dielectric constant higher than that of nitride. For example, the high-k dielectric material may include insulating metal oxides such as hafnium oxide and/or aluminum oxide. The peripheral gate insulating layer 114 may be formed to be thicker than the cell gate insulating layer 106. The peripheral gate insulating layer 114 may be multi-layered.

A preliminary peripheral gate electrode 116 and a mask layer 118 may be sequentially formed on the peripheral gate insulating layer 114 in the peripheral region. The preliminary peripheral gate electrode 116 may cover the substrate 100 in the peripheral region. The preliminary peripheral gate electrode 116 may include a semiconductor doped with dopants (e.g., doped polysilicon), a conductive metal nitride (e.g., titanium nitride (TiN), tantalum nitride (TaN), and/or tungsten nitride (WN)), and/or metal (e.g., ruthenium (Ru), iridium (Ir), titanium (Ti), tungsten (W), and/or tantalum (Ta)). In some embodiments, the preliminary peripheral gate electrode 116 may be formed of a doped polysilicon. The mask layer 118 may include oxide, nitride, and/or oxynitride. In some embodiments, the mask layer 118 may be formed of oxide.

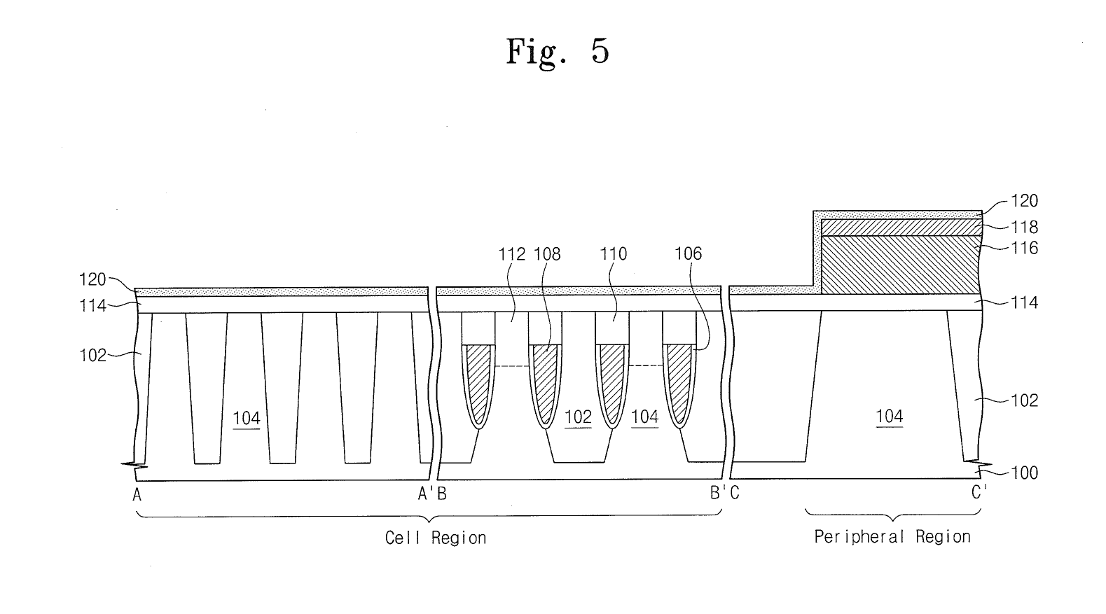

Referring to FIG. 5, an etch stop layer 120 may be formed on the entire surface of the substrate 100. The etch stop layer 120 may include oxide, nitride, and/or oxynitride. In some embodiments, the etch stop layer 120 may be formed of nitride. The etch stop layer 120 may include a material having an etch selectivity with respect to the peripheral gate insulating layer 114.

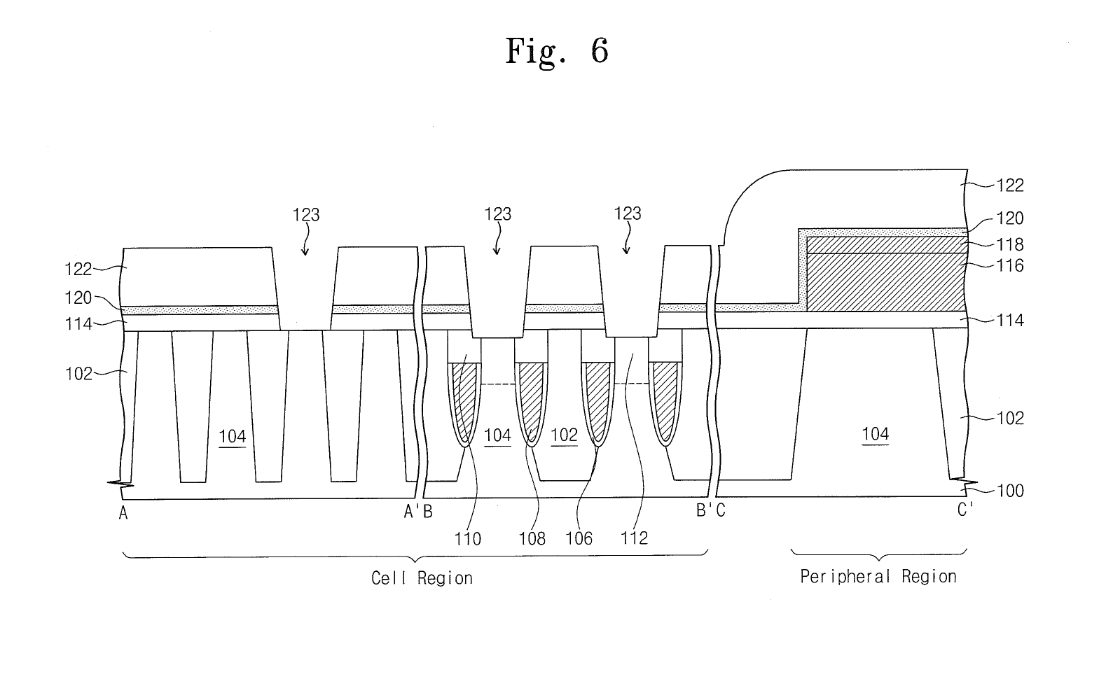

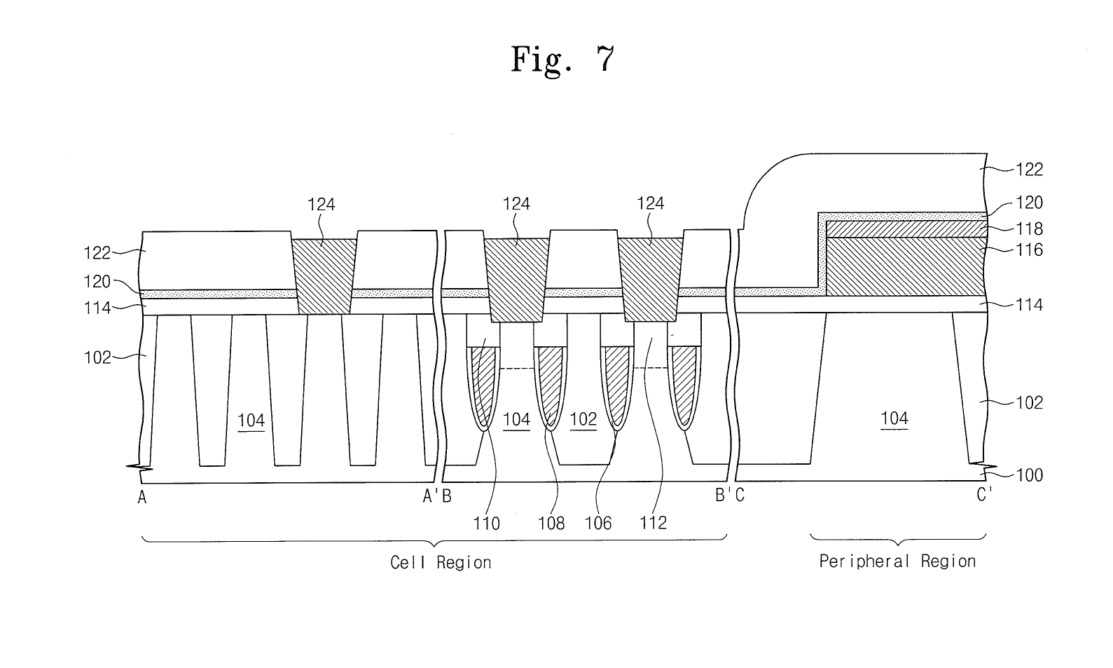

Referring to FIG. 6, a first insulating layer 122 may be formed on the entire surface of the substrate 100 having the etch stop layer 120. The first insulating layer 122 may include oxide, nitride, and/or oxynitride. The first insulating layer 122 may include a material having an etch selectivity with respect to the etch stop layer 120.

An opening 123 may be formed to penetrate the first insulating layer 122, the etch stop layer 120, and the peripheral insulating layer 114 in the cell region. The opening 123 may expose the common source region in the cell region. A mask pattern may be formed on the first insulating layer 122 and the first insulating layer 122, the etch stop layer 120, and the peripheral insulating layer 114 may be successively etched using the mask pattern as an etch mask by performing a dry etching process. Thus, the opening 123 may be formed.

Referring to FIG. 7, a first contact plug 124 may be formed in the opening 123. The first contact plug 124 may include a conductive material. For example, the first contact plug 124 may include a doped semiconductor material (e.g., doped polysilicon), a metal-semiconductor compound (e.g., metal silicide such as tungsten silicide and/or titanium silicide), a conductive metal nitride (e.g., titanium nitride, tantalum nitride, and/or tungsten nitride), and/or metal (e.g., titanium, tungsten, and/or tantalum). In some embodiments, the first contact plug 124 may be formed of doped polysilicon.

A conductive layer may be formed on the first insulating layer 122 to fill the opening 123 and the conductive layer may be etched until a top surface of the first insulating layer 122, thereby forming the first contact plug 124. The conductive layer for the first contact plug 124 may be formed by a CVD process and/or a PVD process. The process etching the conductive layer may be performed by a dry etching process and/or a CMP process. A top surface of the first contact plug 124 may be lower than a top surface of the first insulating layer 122 for planarization before formation of a bit line structure.

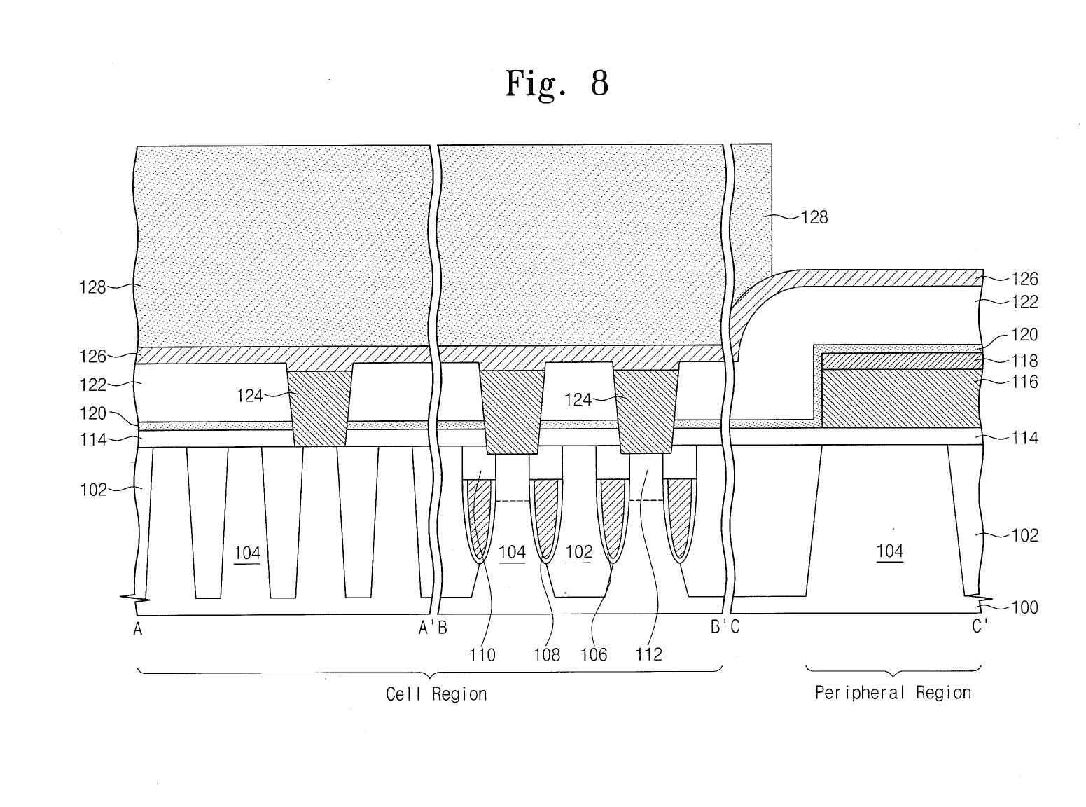

Referring to FIG. 8, a buffer layer 126 may be formed on the surface of the substrate 100 having the first contact plug 124. The buffer layer 126 may include oxide, nitride, and/or oxynitride. In some embodiments, the buffer layer 126 may be formed of oxide. The buffer layer 126 may include a material having an etch selectivity with respect to the etch stop layer 120.

A photoresist pattern 128 exposing the peripheral region may be formed on the substrate 100 having the buffer layer 126. The photoresist pattern 128 may be laterally spaced apart from the active region 104 of the peripheral region. Thus, the photoresist pattern 128 may not overlap a portion of the device isolation layer 102 between the cell region and the peripheral region.

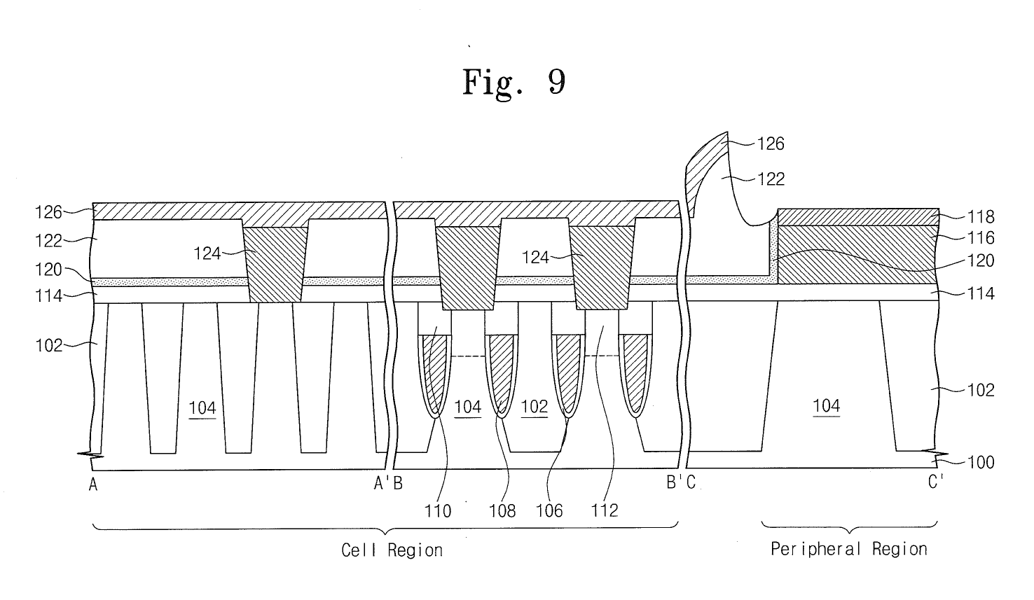

Referring to FIG. 9, the buffer layer 126 and the first insulating layer 122 on the preliminary peripheral gate electrode 116 in the peripheral region may be etched using the photoresist pattern 128 as an etch mask to be removed. After the buffer layer 126 and the first insulating layer 122 on the preliminary peripheral gate electrode 116 in the peripheral region are removed, the photoresist pattern 128 on the buffer layer 126 in the cell region is removed. The mask layer 118 on the preliminary peripheral gate electrode 116 remains and the etch stop layer 120 on one sidewall of the preliminary peripheral gate electrode 116 remains.

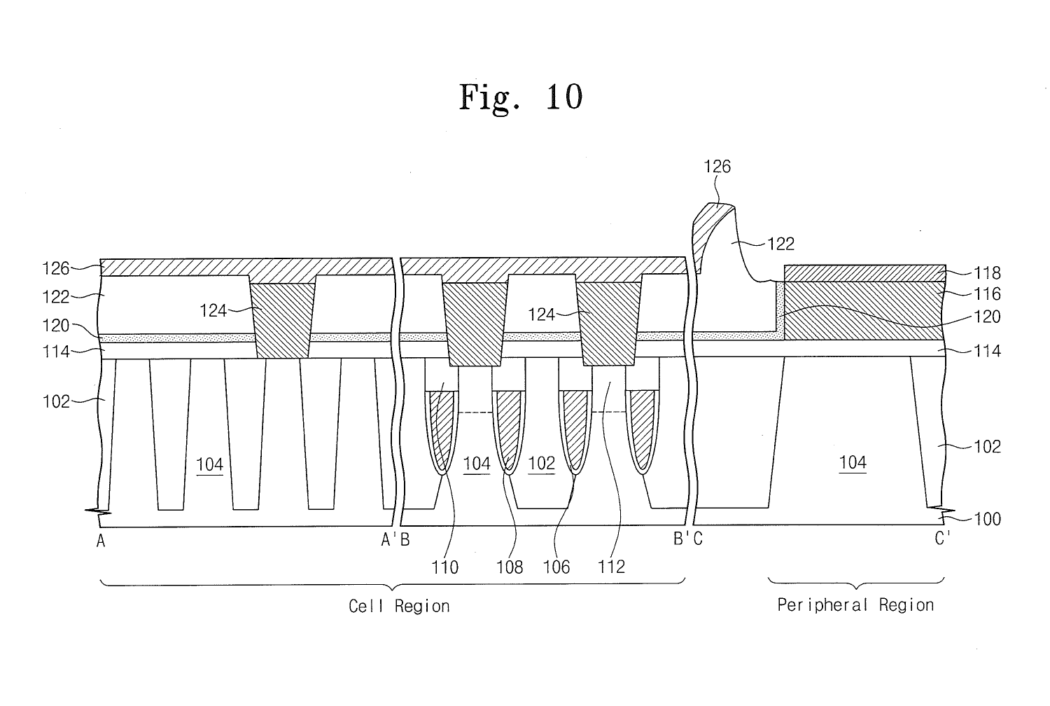

Referring to FIG. 10, an etching process using the buffer layer 126 as an etch mask may be performed to etch the etch stop layer 120 remaining on the one sidewall of the preliminary peripheral gate electrode 116. Thus, a portion of the etch stop layer 120 remaining on the one sidewall of the preliminary peripheral gate electrode 116 is removed such that the top surface of the etch stop layer 120 on the sidewall of the preliminary peripheral gate electrode 116 is lower than a top surface of the preliminary gate electrode 116. As a result, it is possible to prevent a stringer, which may be generated if the etch stop layer 120 is formed before the preliminary gate electrode 116 is formed. Thus, a semiconductor device having improved reliability may be realized without undue reduction of production efficiency.

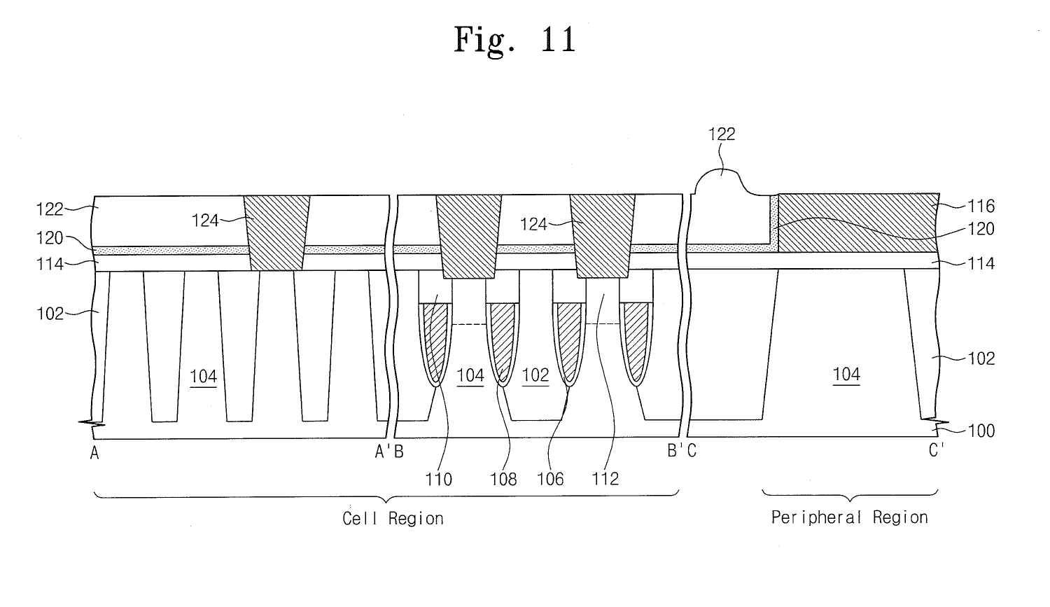

Referring to FIG. 11, the buffer layer 126 in the cell region and the mask layer 118 in the peripheral region may be removed. An upper portion of the first insulating layer 122 may be partially removed. Thus, a top surface the first insulating layer 122 in the cell region may be planarized such that it is disposed at substantially the same level as the top surface of the first contact plug 124.

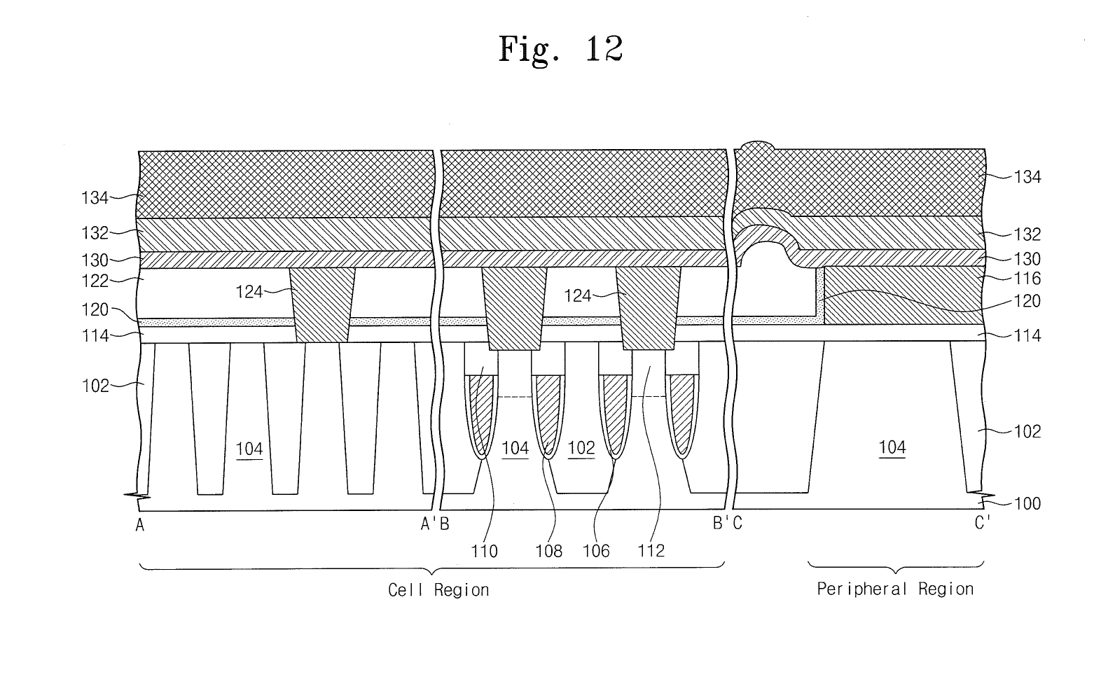

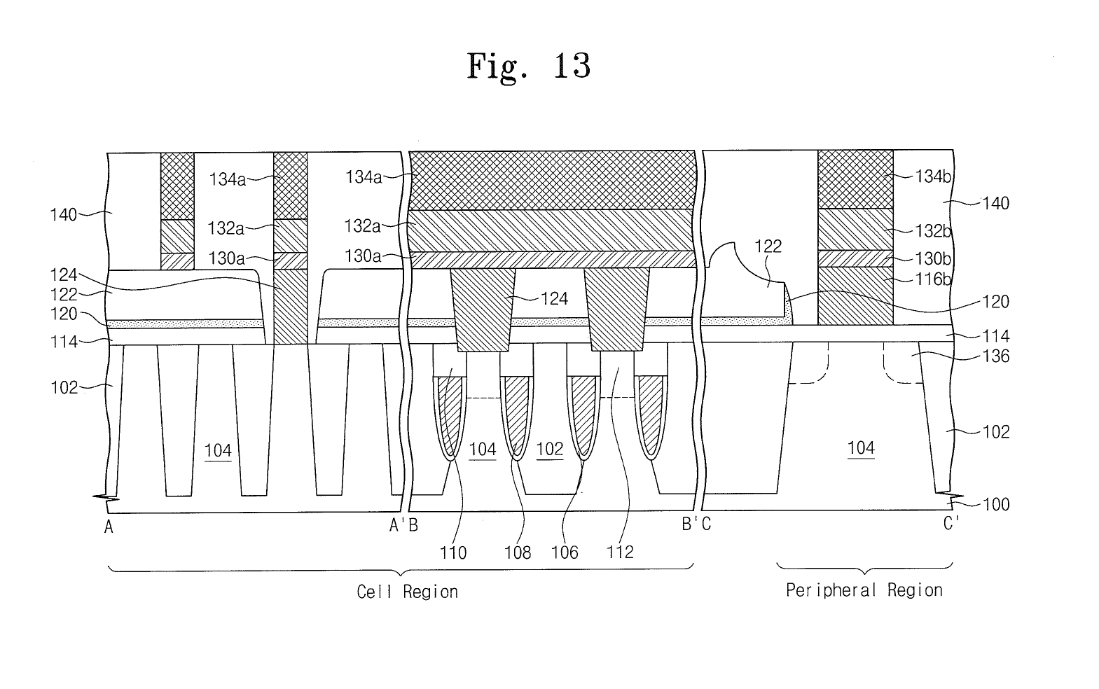

Referring to FIGS. 12 and 13, an interconnection layer including a barrier layer 130, a metal layer 132 and a capping layer 134 sequentially formed may be formed on the substrate 100 having the first insulating layer 122 substantially planarized. The interconnection layer may be electrically connected to the first contact plug 124 in the cell region and preliminary peripheral gate electrode 116 in the peripheral region. The barrier layer 130 may include a conductive metal nitride (e.g., titanium nitride, tantalum nitride, and/or tungsten nitride). The metal layer 132 may include metal (e.g., ruthenium (Ru), iridium (Ir), titanium (Ti), tungsten (W), and/or tantalum (Ta)). The capping layer 134 may include oxide, nitride, and/or oxynitride.

The interconnection layer in the cell region may be patterned to form a bit line structure connected to the first contact plug 124 in cell region. The interconnection layer and the preliminary peripheral gate electrode 116 in the peripheral region may be patterned to form a peripheral gate electrode 116b and upper structure including stacked overlying regions 130b, 132b and 134b in the peripheral region. The bit line structure and the upper structure may be formed simultaneously. The bit line structure may include a first barrier pattern 130a, a first metal pattern 132a, and a first capping pattern 134a sequentially stacked. The upper structure may include a second barrier pattern 130b, a second metal pattern 132b, and a second capping pattern 134b. As described with reference to FIGS. 1, 2A, and 2B, the bit line structure may be formed to have a linear shape extending in a second direction crossing the trench. In some embodiments, the peripheral gate insulating layer 114, the peripheral gate electrode 116b, and the upper structure sequentially stacked in the peripheral region may form a peripheral gate pattern.

As described above, the bit line structure in the cell region and the upper structure in the peripheral region may be formed by the patterning process. In some embodiments, the bit line structure and the upper structure may be formed by a damascene process. In other words, a second insulating layer including first and second openings may be formed on the first insulating layer 122, and the first patterns 130a, 132a, and 134a may be formed in the first opening and the second patterns 130b, 132b, and 134b may be formed in the second opening. In this case, before the second insulating layer having the first and second openings is formed, the preliminary peripheral gate electrode 116 may be patterned to form the peripheral gate electrode 116a. The first opening may expose the first contact plug 124 and the second opening may expose the peripheral gate electrode 116a.

Peripheral dopant regions 136 may be formed in the active region 104 at both sides of the peripheral gate electrode 116a in the peripheral region. The peripheral dopant regions 136 may correspond to source and drain regions. Bottom surfaces of the peripheral dopant regions 136 may be disposed at a predetermined depth from the top surface of the active region 104 of the peripheral region. After a photoresist pattern exposing the peripheral region is formed on the substrate having the bit line and upper structures, dopants may be injected into the active region 104 of the peripheral region by an ion implantation process using the upper structure on the peripheral gate electrode 116a as a mask, thereby forming the peripheral dopant regions 136. The dopant in the peripheral dopant regions 136 may be, for example, phosphorus (P) and/or boron (B). In some embodiments, the bottom surfaces of the peripheral dopant regions 136 may be disposed at a level higher than the bottom surface of the device isolation layer 102.

Referring to FIG. 2B again, a second insulating layer 140 may be formed on the first insulating layer 122 to expose top surfaces of the bit line structure and the upper structure. The second insulating layer 140 may be formed by a CVD process. The second insulating layer 140 may include oxide, nitride, and/or oxynitride.

Contact holes 145 penetrating the second insulating layer 140, the first insulating layer 122, the etch stop layer 120, and the peripheral gate insulating layer 114 in the cell region may be formed. The contact holes 145 may expose the drain regions D, respectively. A mask pattern may be formed on the second insulating layer 140 and then the second insulating layer 140, the first insulating layer 122, the etch stop layer 120, and the peripheral gate insulating layer 114 may be successively etched by a dry etching process, thereby forming the contact holes 145.

Since the etch stop layer 120 is formed under the bit line structure, it is possible to reduce a recessed depth of the substrate 100 of the active regions and to improve uniformity of the recessed depths throughout the substrate 100 in the subsequent etching process for formation of the second contact plug 150. Thus, refresh deterioration may be reduced to realize the semiconductor device with improved reliability.

A second contact plug 150 may be formed in each of the contact holes 145. The second contact plug 150 may include a conductive material. For example, the second contact plug 150 may include a doped semiconductor material (e.g., doped polysilicon), a metal-semiconductor compound (e.g., metal silicide such as tungsten silicide and/or titanium silicide), a conductive metal nitride (e.g., titanium nitride, tantalum nitride, and/or tungsten nitride), and/or metal (e.g., titanium, tungsten, and/or tantalum).

A conductive layer may be formed on the second insulating layer 140 to fill the contact holes 145 and then the conductive layer may be etched until a top surface of the second insulating layer 140 is exposed, thereby forming the second contact plugs 150. The conductive layer may be formed by, for example, a CVD process and/or a PVD process. The conductive layer may be etched by a dry etching process and/or a CMP process.

A data storage element 210 may be formed on the second insulating layer and may be electrically connected to each of the second contact plugs 150. As described with reference to FIGS. 3A and 3B, the data storage element 210 may be realized in various forms.

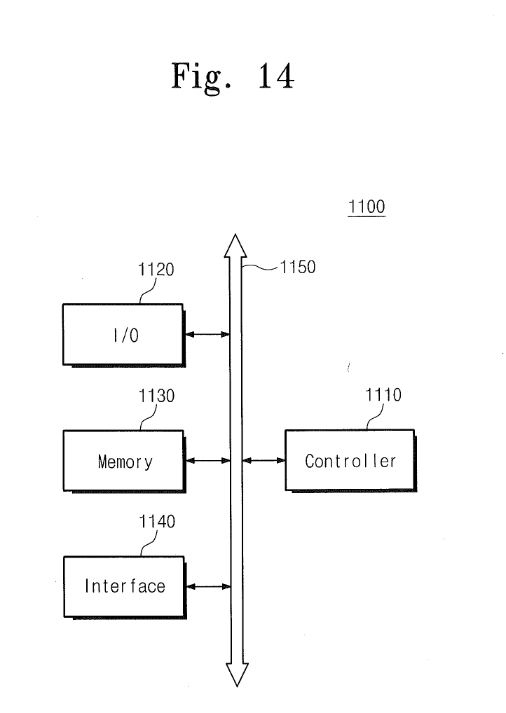

FIG. 14 is a schematic block diagram illustrating an example of memory systems including semiconductor devices according to some embodiments of the inventive subject matter.

Referring to FIG. 14, a memory system 1100 may be applied to a personal digital assistant (PDA), a portable computer, a web tablet, a wireless phone, a mobile phone, a digital music player, a memory card and/or other electronic products. The other electronic products may receive and/or transmit information data by wireless.

The memory system 1100 includes a controller 1110, an input/output (I/O) unit 112 such as a keypad, a keyboard and a display unit, a memory 1130, an interface unit 1140, and a data bus 1150. The memory 1130 and the interface unit 1140 communicate with each other through the data bus 1150.

The controller 1110 may include a microprocessor, a digital signal processor, a microcontroller and/or another logic device. The other logic device may have a similar function to any one of the microprocessor, the digital signal processor and the microcontroller. The memory 1130 may store commands performed by the controller 1110. The I/O unit 1120 may receive data or a signal from the outside of the system 1100 and/or output data or a signal to the outside of the system 1100. For example, the I/O unit 1120 may include a keyboard, a keypad, and/or a display device.

The memory 1130 includes the memory device according to some embodiments of the inventive subject matter. The memory may further include another kind of a memory, a volatile memory capable of randomly accessing, and/or other various kinds of memories.

The interface unit 1140 may transmit electrical data to a communication network and/or may receive electrical data from a communication network.

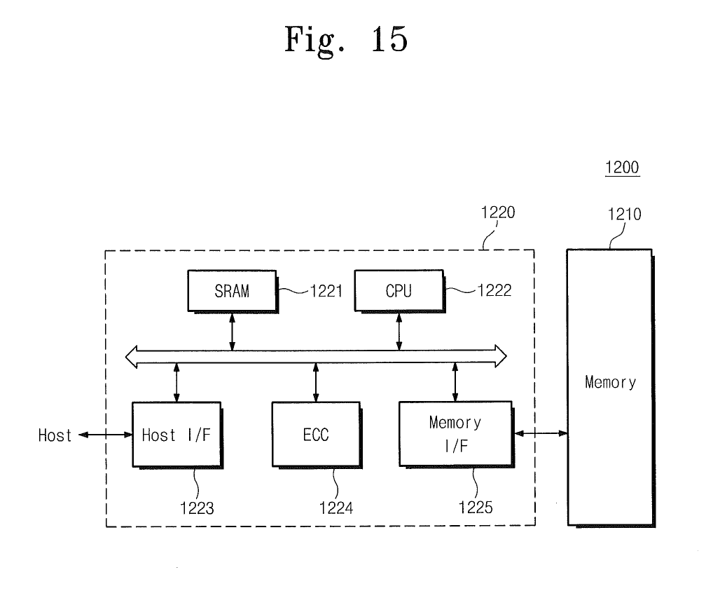

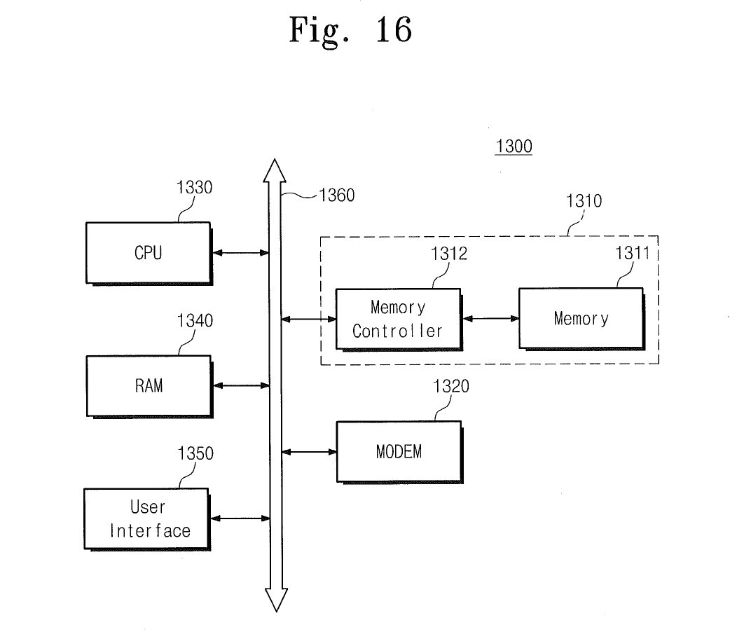

FIG. 15 is a schematic block diagram illustrating an example of memory cards including semiconductor devices according to some embodiments of the inventive subject matter.

Referring to FIG. 15, a memory device 1210 including the semiconductor device according to some embodiments of the inventive subject matter is installed in a memory card 1200 for storing mass data. The memory card 1200 according to some embodiments of the inventive subject matter includes a memory controller 1220 that controls data communication between a host and the memory device 1210.

A static random access memory (SRAM) 1221 is used as an operation memory of a central processing (CPU) unit 1222 corresponding to a processing unit. A host interface (I/F) unit 1223 may be configured to include a data communication protocol of the host connected to the memory card 1200. An error check and correction (ECC) block 1224 checks and corrects errors of data which are read out from the memory device 1210 having multi-bit characteristic. A memory interface (I/F) unit 1225 is interfaced with the memory device 1210 including the semiconductor device according to some embodiments of the inventive subject matter. The CPU unit 1222 controls overall operations for data communication of the memory controller 1220. Even though not shown in the drawings, the memory card 1200 may further include a read only memory (ROM) device that stores code data to interface with the host.

Due to the semiconductor device, the memory card, and/or the memory system described above, a high integrated memory system can be provided. Particularly, the semiconductor device according to some embodiments of the inventive subject matter may be provided to the memory system such as solid state disks (SSD) that are used as hard disks of computer systems. In this case, the high integrated memory system can be realized.

FIG. 16 is a schematic block diagram illustrating an example of data processing systems including semiconductor devices according to some embodiments of the inventive subject matter.

Referring to FIG. 16, a memory system 1310 is installed in a data processing system 1300 such as a mobile device or a desktop computer. The memory system 1310 includes a memory device 1311 including the semiconductor device according to some embodiments of the inventive subject matter and a memory controller 1312 controlling overall data communications between a data bus 1360 and the memory device 1311. The data processing system 1300 according to some embodiments of the inventive subject matter includes a modulator-demodulator (MODEM) 1320, a central processing unit (CPU) 1330, a random access memory (RAM) 1340 and a user interface unit 1350 that are electrically connected to the memory system 1310 through the data bus 1360. The memory system 1310 may have substantially the same configuration as the memory system described with reference to FIG. 14.

The memory system 1310 may store data processed by the CPU 1330 and/or data transmitted from an external system. Here, the memory system 1310 may be realized as a solid state drive (SSD). In this case, the information processing system 1300 may stably and reliably store massive data into the memory system 1310. Additionally, as reliability becomes improved, the flash memory system 1310 may reduce a resource for correcting errors to provide high speed of data communication to the data process system 1300. Although not shown in the drawings, the data processing system 1300 may further include an application chipset, an image signal processor (ISP), and/or an input/output unit.

The memory device and/or the memory system including the semiconductor devices according to some embodiments of the inventive subject matter may be encapsulated using various packaging techniques. For example, the memory device and/or the memory system according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (S SOP) technique, a thin small outline package (TSOP) technique, a thin quad flat package (TQFP) technique, a system in package (SIP) technique, a multi chip package (MCP) technique, a wafer-level fabricated package (WFP) technique and a wafer-level processed stack package (WSP) technique.

As described above, in the semiconductor device according to some embodiments of the inventive subject matter, since the etch stop layer is formed under the bit line structure subsequently formed, it is possible to reduce a recessed depth of the substrate of the active regions and to improve uniformity of the recessed depths throughout the substrate in the subsequent etching process for formation of the second contact plug. Thus, refresh deterioration may be minimized to realize the semiconductor device with improved reliability and the method of fabricating the same. Additionally, since the etch stop layer is formed after the preliminary peripheral gate electrode is formed, it is possible to prevent a stringer, which may be generated in the case that the etch stop layer 120 is formed before the preliminary gate electrode 116 is formed, form generating. Thus, the semiconductor device having improved reliability may be realized without reduction of production efficiency.

While the inventive subject matter has been described with reference to example embodiments, it will be apparent to those skilled in the art that various changes and modifications may be made without departing from the spirit and scope of the inventive subject matter. Therefore, it should be understood that the above embodiments are not limiting, but illustrative. Thus, the scope of the inventive subject matter is to be determined by the broadest permissible interpretation of the following claims and their equivalents, and shall not be restricted or limited by the foregoing description.

1-8. (canceled)

9. A semiconductor device comprising:
a substrate;
a device isolation layer defining active regions in the substrate;
buried gate patterns in the substrate extending along a first direction and crossing the active regions;
an etch stop layer and a first insulating layer sequentially stacked on the substrate;
first contact plugs penetrating the first insulating layer and the etch stop layer to electrically contact the active regions between the buried gate patterns;
bit line structures disposed on the first insulating layer and electrically connected to the first contact plugs, the bit line structures extending in a second direction transverse to the first direction;
a second insulating layer covering the bit line structures; and
second contact plugs penetrating the second insulating layer, the first insulating layer, and the etch stop layer to electrically contact the active regions between the bit line structures.

10. The semiconductor device of claim 9, wherein the buried gate patterns each comprise:
a cell gate insulating layer disposed on an inner surface of a trench in the substrate;
a cell gate electrode on the cell gate insulating layer in the trench; and
a cell gate capping pattern disposed on the cell gate electrode in the trench.

11. The semiconductor device of claim 9, wherein the bit line structures each comprise a barrier pattern, a metal pattern, and a capping pattern stacked on the first insulating layer.

12. The semiconductor device of claim 9, wherein the first contact plugs comprise polysilicon.

13. The semiconductor device of claim 9, wherein the substrate comprises a cell region and a peripheral region and wherein the buried gate patterns are disposed in the cell region, and wherein the semiconductor device further comprises:
a gate pattern comprising a peripheral gate insulating layer, a peripheral gate electrode, and an upper structure stacked on an active region in the peripheral region,
wherein the upper structure comprises the same material as the bit line structures.

14. The semiconductor device of claim 13, wherein a portion of the etch stop layer on the device isolation layer between the cell region and the peripheral region has a height lower than a height of the peripheral gate electrode.

15. A semiconductor device comprising:
a substrate;
a device isolation layer defining elongate active regions in the substrate;
parallel linear buried gate patterns in the substrate extending along a first direction to obliquely crossing the active regions;
a first insulating layer on the parallel linear buried gate patterns;
first contact plugs penetrating the first insulating layer to electrically contact the active regions between the parallel linear buried gate patterns;
parallel linear bit line structures disposed on the first insulating layer and electrically connected to the first contact plugs, the bit line structures extending in a second direction transverse to the first direction to obliquely cross the active regions;
a second insulating layer covering the parallel linear bit line structures; and
second contact plugs penetrating the second insulating layer and the first insulating layer to electrically contact the active regions between the bit line structures.

16. The semiconductor device of claim 15, further comprising an etch stop layer on the parallel linear buried gate patterns, wherein the first insulation layer is disposed on the etch stop layer, and wherein the first and second contact plugs pass through the etch stop layer.

17. The semiconductor device of claim 15, wherein the substrate comprises a cell region and a peripheral region and wherein the buried gate patterns are disposed in the cell region, and wherein the semiconductor device further comprises:
a gate pattern comprising a peripheral gate insulating layer, a peripheral gate electrode, and an upper structure stacked on an active region in the peripheral region,
wherein the upper structure comprises the same material as the bit line structures.

18. The semiconductor device of claim 17, wherein a portion of the etch stop layer on the device isolation layer between the cell region and the peripheral region has a height lower than a height of the peripheral gate electrode.

19. The semiconductor device of claim 15, wherein the parallel linear bit line structures each comprise a barrier pattern, a metal pattern, and a capping pattern stacked on the first insulating layer.

20. The semiconductor device of claim 15, wherein the first contact plugs comprise polysilicon.
